(19) United States
(12) Patent Application Publication
(10) Pub. No.: US 2021/0343701 A1
(43) Pub. Date: Nov. 4, 2021

(54) CIRCUIT THAT PREVENTS DEVICE BODY DIODE CONDUCTION

(71) Applicant: U.S Army Combat Capabilities Development Command, Army Research Laboratory, Adelphi, MD (US)

(72) Inventor: Damian P. Urciuoli, Bowie, MD (US)

(21) Appl. No.: 16/861,274

(22) Filed: Apr. 29, 2020

(51) Int. Cl. H01L 27/02; H01L 29/16; H01L 29/778

(52) U.S. Cl. CPC H01L 27/0266; H01L 29/7786; H01L 29/1608

(57) ABSTRACT

A circuit comprising a first device (e.g., a high voltage MOSFET) coupled in series with a second device (e.g., a low voltage MOSFET or HEMT). The first device comprises a body diode. Additionally, the circuit comprises a diode coupled across the pair of devices. The diode is arranged antiparallel to the first device. In one exemplary embodiment, the first device is a SiC MOSFET and the second device is a Si MOSFET or GaN HEMT.

### GOVERNMENT INTEREST

The invention described herein may be manufactured, used and licensed by or for the U.S. Government.

### BACKGROUND

### Field

Embodiments of the present invention generally relate to devices comprising body-diodes such as, for example, metal oxide semiconductor field effect transistors (MOSFET), metal insulator semiconductor field effect transistors (MISFET) and the like and, more particularly, to a circuit that prevents device body-diode conduction.

### Description of the Related Art

Silicon carbide (SiC) is a wide-band-gap semiconductor material with several properties that result in excellent performance for power-electronic devices. However, SiC material commonly has a type of crystal structure defect called a basal-plane dislocation (BPD) which can introduce stacking faults during bipolar current flow. BPDs can be activated to propagate stacking faults resulting in increased drain leakage during MOSFET blocking (off state) and reduced current flow during MOSFET conduction (on state). The degradation of performance due to stacking faults can be more severe for higher voltage rated devices having thicker structures.

FIG. 1 depicts a common solution to prevent or limit body-diode conduction in SiC MOSFETs 100, where a SiC Schottky barrier diode (SBD) 102 is connected in parallel with the MOSFET body diode 104. This connection is also referred to as an anti-parallel connection of the diode 102 to the MOSFET 100, because the MOSFET 100 and diode 102 have opposite forward-current directions (forward current flows in the MOSFET 100 from drain to source and in the diode 102 from anode to cathode). The SBD 102 can be integrated into the MOSFET structure, placed on a separate portion of the MOSFET chip, or externally connected to the MOSFET terminals. The SBD 102 can be selected or designed to have a lower forward voltage drop than the MOSFET body diode 104 to provide a preferential path for current flow, thereby effectively bypassing the MOSFET body diode 104. The SBD 102 benefits from unipolar conduction and is therefore not susceptible to stacking-fault expansion from any BPDs that may be present in its structure. However, SBD forward voltage increases with current, and as the forward current increases, if SBD forward voltage exceeds the forward threshold-voltage of the MOSFET body diode, a portion of the current is conducted through the body diode 104 as bipolar current. Therefore, SBDs 102 can be required to have relatively large areas to ensure that they conduct most or all of the peak current per phase in a power converter or other MOSFET circuit where high current is controlled.

An additional background art solution to limit bipolar current in the MOSFET body diode is to turn on the MOSFET 100 to allow current to flow through its channel from source to drain. This flow of current in the reverse direction through the MOSFET 100 is referred to as synchronous rectification in the operation of a power converter. However, in most power converters, a MOSFET 100 used for synchronous rectification cannot be turned on before the current begins to flow through either its body diode 104 or an anti-parallel-connected SBD 102. Furthermore, the initial current to be conducted by the body diode 104 or the SBD 102 generally includes the peak current of the converter switching cycle. Even after the MOSFET 100 is turned on, a sufficiently large current through the MOSFET channel from source to drain could still produce enough voltage drop in the channel and an antiparallel-connected SBD 102 to produce bipolar current flow in the MOSFET body diode 104. While synchronous rectification may help limit the duration of bipolar current flow in the MOSFET body diode 104, generally it cannot prevent it.

FIG. 2 depicts a background art solution where an additional blocking diode 206 is connected in series with the MOSFET 200 to block current flowing through the body diode 204, with the cathode of the blocking diode 206 connected to the MOSFET drain. The SBD or other type of anti-parallel diode 202 is connected across both the MOSFET 200 and the blocking diode 206 with the anode of the SBD 202 connected to the source of the MOSFET 200 and the cathode of the SBD 202 connected to the anode of the blocking diode 206. However, during forward conduction (drain to source) of the MOSFET 200, the forward voltage of the blocking diode 206 adds to the MOSFET forward voltage, resulting in a relatively high total forward voltage for the overall circuit. During reverse conduction, all of the current must pass through the anti-parallel diode. Furthermore, the blocking diode 206 prevents the MOSFET 200 from reverse conducting (synchronous rectification) to reduce conduction losses.

Therefore, there is a need in the art for an improved circuit to prevent device body-diode conduction.

### SUMMARY

Embodiments of the invention include a circuit comprising a first device (e.g., a high voltage MOSFET) coupled in series with a second device (e.g., a low voltage MOSFET or HEMT). The first device comprises a body diode. Additionally, the circuit comprises a diode coupled across the pair of devices. The diode is arranged antiparallel to the first device. In one exemplary embodiment, the first device is a SiC MOSFET and the second device is a Si MOSFET or GaN HEMT.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a depiction of a background art schematic of a MOSFET circuit including an anti-parallel diode;

FIG. 2 is a background art schematic of a MOSFET circuit including an anti-parallel diode and a blocking diode;

FIG. 3 depicts a schematic of a circuit of an embodiment of the current invention;

FIG. 4 depicts an embodiment of a physical structure of a MOSFET circuit in accordance with an embodiment of the invention; and

FIG. 5 depicts a second embodiment of a physical structure of a MOSFET circuit in accordance with an embodiment of the invention.

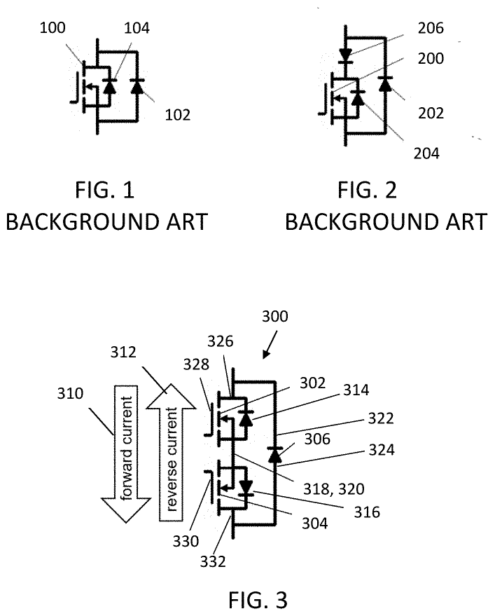

### DETAILED DESCRIPTION

Embodiments of the invention include a circuit comprising a first device coupled in series with a second device. The first device comprises a body diode. The circuit further comprises a diode coupled across the pair of devices. The diode is arranged antiparallel to the first device. In some embodiments, the first device is a SiC MOSFET and the second device is a Si MOSFET or gallium-nitride high electron mobility transistor (GaN HEMT). In one exemplary embodiment, the first device is a high voltage MOSFET and the second device is a low voltage MOSFET. The diode provides a high current path for reverse current flowing opposite to the normal current flow direction of the first device and, as such, is sometimes referred to as an antiparallel diode. The diode is typically a Junction Barrier Schottky (JBS) diode. Embodiments of the invention are applicable to any situation where body diode current flow needs to be prevented in a device.

The following exemplary embodiment describes the first device as a high-voltage SiC MOSFET and the second device as a low voltage Si MOSFET. This combination should be considered to be an exemplary embodiment. Other embodiments are applicable in circuits where the first device comprises a body-diode such as MOSFETs, MISFETs and the like. Also, the second device may comprise other low voltage transistors such as a GaN HEMT. Those skilled in the art will realize that embodiments of the invention have applicability with various combinations of devices that utilize various materials and voltage levels.

FIG. 3 depicts an embodiment of the invention where a MOSFET circuit 300 comprises a first MOSFET 302 connected in a common-source configuration with a second MOSFET 304 (i.e., sources 318 and 320 are connected to one another) and a diode 306 having its cathode 322 connected to the drain 326 of the first MOSFET 302 and its anode 324 connected to the drain 332 of the second MOSFET 304. In one embodiment, the first MOSFET 302 may be a SiC MOSFET having a high blocking voltage (e.g. >1.2 kV), the second MOSFET 304 may be a silicon (Si) MOSFET having a low blocking voltage (e.g. 20 V to 50 V), and the diode 306 may be a SiC JBS diode having a blocking voltage greater than or nearly equal to that of the SiC MOSFET 302. In this implementation, forward current 310 is conducted through the first MOSFET 302 in the forward direction and through the second MOSFET 304 in the reverse direction when both MOSFETs 302 and 304 are turned on. For current in the reverse direction 312, the blocking voltage of the second MOSFET 304 is sufficiently high to ensure that when both MOSFETs 302 and 304 are turned off, all reverse current flows through the JBS diode 306, and that no current flows through the body diode 314 of the first MOSFET 302. However, synchronous rectification of the first MOSFET 302 can be achieved by turning on both MOSFETs 302 and 304 to allow current in the reverse direction 312 to flow through the second MOSFET 304 in the forward direction and the through the first MOSFET 302 in the reverse direction.

More specifically, to ensure the second MOSFET's blocking function works properly, the blocking voltage level of the second MOSFET 304 (low voltage) is selected to ensure that the MOSFET voltage is more than the maximum voltage created across the anti-parallel diode 306 when peak reverse current is flowing through the anti-parallel diode 306. In this manner, the second MOSFET 304 will not allow reverse current to flow through the body diode 314 of the first MOSFET 302.

Additionally, in one embodiment, to ensure the forward current 310 flow operates properly, the second MOSFET 304 is generally turned on before the first MOSFET 302. As such, the gate voltage to turn on the second MOSFET 304 is applied to its gate 330 slightly before applying the gate voltage to the gate 328 of the first MOSFET 302.

In one embodiment, the low-voltage MOSFET (second MOSFET 304) has a current rating similar to or greater than that of the high-voltage SiC MOSFET (first MOSFET 302). With both MOSFETs 302 and 304 turned on, during forward conduction of the high-voltage MOSFET 302, the voltage across the reverse conducting low-voltage MOSFET 304 can be smaller than that of a diode 306 having a device area similar to that of the low-voltage MOSFET 304. Therefore, in this mode of operation, the proposed arrangement of devices can provide lower loses than the arrangement of devices shown in FIG. 2 (Background Art). With both MOSFETs 302 and 304 having a common-source connection 318, they can be switched using a single gate driver. However, as mentioned above, the gate driver should be configured to ensure that the low-voltage MOSFET 304 turns on before the high-voltage MOSFET 302 turns on, for the circuit 300 to conduct forward current 310. The proposed arrangement of devices can also allow the anti-parallel diode 306 to have a smaller active area than an external anti-parallel diode or other reverse-current-carrying structures of the background art.

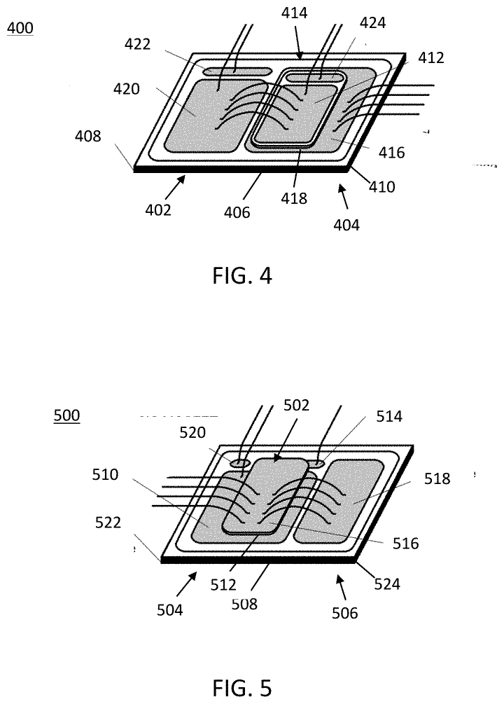

FIG. 4 depicts an embodiment of the invention including a semiconductor chip 400, where a high-voltage SiC MOSFET 402 (first MOSFET) and a SiC Junction Barrier Schottky (JBS) diode 404 having a similar or higher blocking voltage are fabricated in separate active areas on a single chip 406. In this exemplary structure, the MOSFET drain terminal 408 and the diode cathode terminal 410 are shared on one side (for example, the back side) of the chip 406. The separate SiC MOSFET 402 (first MOSFET) and diode 404 active areas of the chip can allow separate unconnected terminals (for example metalized pads) for the SiC MOSFET source 420 and the diode anode 416 on the opposite side (for example, the top side) of the chip 406. In this exemplary embodiment, a discrete low-voltage silicon (Si) MOSFET 414 is mounted on the combined SiC MOSFET and JBS diode chip 406 with the drain 418 of the low-voltage MOSFET 414 electrically connected to (for example, by solder) the anode terminal 416 of the JBS diode 404. The source 412 of the Si MOSFET 414 is electrically connected to the source 420 of the SiC MOSFET 402 (for example, by wire bonds). The SiC MOSFET 402 contains gate 422 and Si MOSFET 414 contains gate 424.

FIG. 5 depicts another embodiment of the invention containing an alternative circuit 500 comprising a low voltage Si MOSFET 502, a high voltage SiC MOSFET 504 and a JBS diode 506, where the discrete low-voltage Si MOSFET 502 is mounted on the combined SiC MOSFET and JBS diode chip 508 with the source 512 of the Si MOSFET 502 electrically connected to (for example, by solder) the source terminal 510 of the high-voltage SiC MOSFET 504. The Si MOSFET gate can be connected to (for example, by solder) an isolated metalized pad 514 on the top surface of the SiC chip 508 that extends out from under the Si MOSFET chip 502. The SiC MOSFET 504 has a gate 520 also located on the top of the chip 508. The drain 516 of the Si MOSFET 502 is electrically connected to the anode 518 of the JBS diode 506 (for example, by wire bonds). The drain 522 of the SiC MOSFET and the cathode 524 of the diode 506 are formed on the backside of the chip 508. The connected devices 400/500 in both these embodiments of FIGS. 4 and 5 can be packaged (for example with additional solder bonds and/or wire bonds) to facilitate external electrical connections to: the electrically-connected SiC MOSFET drain and JBS diode cathode, the electrically-connected Si MOSFET drain and JBS diode anode, the electrically connected sources of the Si and SiC MOSFETs, the SiC MOSFET gate, and the Si MOSFET gate.

Additionally, in both the embodiments of FIGS. 4 and 5, one or more resistors (not shown) may be connected to the gates of the SiC and/or Si MOSFETs, and those resistors may be incorporated into the device package to allow external connection to the gates and/or the resistors.

While the foregoing is directed to embodiments of the present invention, other and further embodiments of the invention may be devised without departing from the basic scope thereof, and the scope thereof is determined by the claims that follow.

REFERENCE NUMERALS
ARL19-26

| | |
|---|---|
| 100 | SiC MOSFET |
| 102 | SiC Schottky barrier diode (SBD) |
| 104 | MOSFET body diode |
| 202 | anti-parallel diode |
| 204 | body diode |
| 206 | blocking diode |
| 300 | MOSFET circuit |
| 302 | first MOSFET (high voltage) |
| 302 | SiC MOSFET |
| 304 | second MOSFET (low voltage) |
| 306 | diode (JBS) |
| 306 | anti-parallel diode |
| 310 | forward current |
| 312 | reverse direction |
| 314 | body diode |
| 318 | source |
| 318 | common-source connection |
| 320 | source |
| 322 | cathode |
| 324 | anode |
| 326 | drain |
| 328 | gate |
| 330 | gate |
| 332 | drain |
| 400 | integrated circuit |
| 402 | high-voltage SiC MOSFET |
| 404 | SiC Junction Barrier Schottky (JBS) diode |
| 406 | single-chip |
| 408 | MOSFET drain terminal |
| 410 | diode cathode terminal |
| 412 | Si MOSFET source |
| 414 | Si MOSFET (low voltage) |
| 416 | diode anode |
| 418 | drain |
| 420 | source |
| 422 | gate |
| 500 | alternative circuit |
| 502 | Si MOSFET |
| 504 | SiC MOSFET |
| 506 | JBS diode |
| 508 | SiC chip |
| 510 | source terminal |
| 514 | isolated metalized pad |
| 516 | drain |
| 518 | anode |
| 520 | gate |
| 522 | drain |
| 524 | cathode |

1. A circuit comprising:
a first device having a drain, source and gate with a body-diode coupled between the drain and the source;
a second device having a drain, source and gate;
a diode having a cathode and anode; and
where the source of the first device is connected to the source of the second device, and the cathode of the diode is connected to the drain of the first device and the anode of diode is connected to the drain of the second device, where the diode is antiparallel to the first device.

2. The circuit of claim 1 wherein the first device is a MOSFET, high-voltage MOSFET, a SiC MOSFET or a MISFET.

3. The circuit of claim 1 wherein the second device is a MOSFET, low-voltage MOSFET or a GaN HEMT.

4. The circuit of claim 1 wherein the diode is a Junction Barrier Schottky (JBS) diode.

5. The circuit of claim 1 wherein the first device is a high-voltage MOSFET, the second device is a low-voltage MOSFET, and the diode is a JBS diode.

6. The circuit of claim 5 wherein the high voltage MOSFET is a SiC MOSFET and the low voltage MOSFET is a Si MOSFET.

7. An integrated circuit structure comprising:
a first chip comprising a first device having a gate, source and drain with a body-diode coupled between the source and the drain, and a diode having a cathode and anode, where a first surface of the first chip comprises the drain of the first device and a cathode of the diode and a second surface of the first chip comprises the source of the first device, the gate of the first device, and an anode of the diode;
a second chip comprising a second device having a gate, drain and source, where a first surface of the second chip comprises the drain of the second device and the second surface comprises the source and gate of the second device;
wherein the second chip is arranged atop the first chip to position the source of the first device upon the source of the second device; and
wherein the drain of the second device is coupled to the anode of the diode.

8. The integrated circuit structure of claim 7 wherein the first device is a MOSFET, high-voltage MOSFET, MISFET, or SiC MOSFET.

9. The integrated circuit structure of claim 7 wherein the second device is a MOSFET, low-voltage MOSFET, Si MOSFET or GaN HEMT.

10. The integrated circuit structure of claim 7 wherein the diode is a Junction Barrier Schottky (JBS) diode.

11. The integrated circuit structure of claim 7 wherein the first MOSFET is a high-voltage MOSFET, the second MOSFET is a low-voltage MOSFET, and the diode is a JBS diode.

12. The integrated circuit structure of claim 11 wherein the high voltage MOSFET is a SiC MOSFET and the low voltage MOSFET is a Si MOSFET.

13. An integrated circuit structure comprising:
a first chip comprising a first device having a gate, source and drain with a body-diode coupled between the source and drain and a diode having a cathode and anode, where a first surface of the first chip comprises the drain of the first device and a cathode of the diode and a second surface of the first chip comprises the source of the first device and an anode of the diode;
a second chip comprising a second device having a gate, drain and source, where a first surface of the second chip comprises the drain of the second device and the second surface comprises the source and gate of the second device;
wherein the second chip is arranged atop the first chip to position the drain of the second device upon the anode of the diode; and
wherein the source of the second device is coupled to the source of the first device.

14. The integrated circuit structure of claim 13 wherein the first device is a high-voltage MOSFET, MOSFET, MISFET or SiC MOSFET.

15. The integrated circuit structure of claim 13 wherein the second device is a MOSFET, low-voltage MOSFET or GaN HEMT.

16. The integrated circuit structure of claim 13 wherein the diode is a Junction Barrier Schottky (JBS) diode.

17. The integrated circuit structure of claim 13 wherein the first device is a high-voltage MOSFET, the second device is a low-voltage MOSFET, and the diode is a JBS diode.

18. The integrated circuit structure of claim 17 wherein the high voltage MOSFET is a SiC MOSFET and the low voltage MOSFET is a Si MOSFET.

19. A method of operating a circuit of claim 1, comprising:
applying a signal to turn on the second device prior to applying a signal to turn on the first device.
